(19) United States
(12) Patent Application Publication
(10) Pub. No.: US 2007/0066072 A1
(43) Pub. Date: Mar. 22, 2007

(54) Method of fabricating semiconductor device

(75) Inventor: Byoung Yoon Suh, Yeojoo-gun (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/527,652

(22) Filed: Sep. 20, 2006

(30) Foreign Application Priority Data
Sep. 22, 2005 (KR) 10-2005-0087964

(51) Int. Cl. H01L 21/302; H01L 21/461

(52) U.S. Cl. 438/704; 438/745

(57) ABSTRACT

Disclosed is a method of manufacturing a semiconductor device using a dual damascene process. A first etching barrier film, an insulation film and a second etching barrier film are formed in sequence on a semiconductor substrate having a first metallic wiring therein and are then selectively etched to form a contact hole. A trench is formed by etching first the etching barrier film and insulation film adjacent to the contact hole. After the contact hole is wet-cleaned, the first etching barrier film is etched and (optionally) a reflection-preventing film and a second metallic wiring are formed. Thus, before forming a metallic wiring, photoresist residues and polymer inside the contact hole can be efficiently removed, dissimilarly to conventional methods which may cause defective deposition of metallic materials due to photoresist residues and polymer that may remain inside the contact hole.

### BACKGROUND OF THE INVENTION

1. Field of the Invention

The present invention relates to a method of fabricating a semiconductor device, and more specifically to, such a method suitable for forming a metallic wiring using a dual damascene process.

2. Background of the Related Art

In order to form a metallic wiring using a damascene process, as is well known in the art, a first insulation film is partially etched and removed to form a contact hole. Thereafter, a conductive material is deposited inside the formed contact hole to form a plug. In one process, a second insulation film is formed on top thereof and then etched to expose the plug. Then, a metallic wiring is formed so as to contact the plug.

In such a method of forming a metallic wiring, a self-aligned contact technique may be used to form a contact hole contacting a lower portion of the device with a metallic wiring layer, and the contact hole and trench may be filled simultaneously with metal for the wiring, thereby forming a plug and a metallic wiring layer. This technique is called a dual damascene process.

In addition, the dual damascene process can simplify manufacturing processes of semiconductor devices to thereby enable to reduce the manufacturing cost. Further, misalignment of the pattern, which may occur during exposure of the plug and metallic wiring trench, can be mitigated.

In manufacturing a semiconductor device having increased degree of integration, the process margin between devices may be reduced, which may result in an increased incidence of short-circuits between conductive layers and worsened electrical properties of devices. In order to avoid these problems, therefore, a damascene process has been widely employed to form a metallic wiring.

FIGS. 1A to 1H show procedures for forming a metallic wiring using a conventional dual damascene process in manufacturing semiconductor devices. Hereafter, the conventional dual damascene process will be explained with reference to FIGS. 1A to 1H.

Referring to FIG. 1A, a first interlayer insulation film 100 is patterned and filled with a first metal to form a contact plug 102. Then, a second interlayer insulation film 104 is patterned and filled with a second metal to form a first metallic wiring 106 on a semiconductor substrate. On top thereof, a first etching barrier film 108, a third interlayer insulation film 110 and a second etching barrier film 112 are formed in sequence. Thereafter, a first photoresist pattern 114 is formed in order to form a contact hole.

In addition, as shown in FIG. 1B, a certain desired region is etched along the first photoresist pattern 114 (i.e., using the first photoresist pattern 114 as a mask) so as to expose the first etching barrier film 108 and form a contact hole 116. Then, the first photoresist pattern 114 is removed.

Thereafter, as shown in FIG. 1C, in order to form a trench, a second photoresist pattern 118 is formed on the semiconductor substrate having the contact hole 116. At this time, a photoresist of certain thickness is embedded in the contact hole 116 formed in the semiconductor substrate.

Furthermore, as shown in FIG. 1D, the second etching barrier film 112 and a desired portion of the third interlayer insulation film 110 are dry-etched (for example, be reactive ion etching [RIE] or the like) along the second photoresist pattern 118 (i.e., using the second photoresist pattern 118 as a mask) to form a trench. Then, the second photoresist pattern 118 is removed, as shown in FIG. 1E. At times, a part of the photoresist 118a may remain in the inner side and lower surfaces of the contact hole 116.

Then, the first etching barrier film 108 at the bottom of the contact hole 116 is removed through a SiN dry-etching method. At this time, as shown in FIG. 1F, the remaining photoresist 118a and SiN react with each other to form polymer and photoresist residues 120. Thereafter, a SiN wet-cleaning process is carried out to remove the polymer and photoresist residues 120. Here, the SiN wet-cleaning process is performed in sequence using DHCl (for approximately 25 to 30 seconds at approximately 250 to 350 RPM), DHF (for approximately 5 to 30 seconds at approximately 400 to 500 RPM) and DNH₄OH (for approximately 3 to 10 seconds at approximately 1400 to 1500 RPM). Here, ‘D’ in DHCl, DHF and DNH₄OH denotes ‘diluted’, i.e., means diluting the HCl, HF and NH₄OH of high concentration.

Then, using a CVD method, a metallic barrier film 122 of TaN/Ta or the like is deposited over the whole top surface of the above-configured semiconductor substrate, as shown in FIG. 1G.

Subsequently, a metallic material of Cu or the like is vapor-deposited on the metallic barrier film 122 of the semiconductor substrate to form a metallic layer. Then, using a CMP process or the like, a planarization process is performed so as to expose the second etching barrier film 112 and, as shown in FIG. 1H, a metallic wiring 124 is formed.

As one example, FIG. 3A shows polymer and residues remaining on the surface and in the contact hole after wet-etching in a conventional manufacturing process of semiconductor devices. FIG. 3B shows a defective deposition of Cu due to the polymer and residues remaining in the contact hole in the conventional manufacturing process. Here, it can be seen from FIGS. 3A and 3B that the polymer and residues remaining in the contact hole leads to a defective deposition of Cu (i.e., an open circuit).

Therefore, in the conventional manufacturing method of semiconductor devices, polymer and photoresist residues due to dry-etching may remain inside the contact hole. The polymer and residues act as an inhibitor when depositing a metallic barrier film (e.g., Ta/TaN or the like) for Cu deposition, thereby leading to a defective deposition of Ta/TaN. Thus, an electronic Cu plating (ECP) may be carried out at the state where a seed Cu is not deposited, so that the Cu may not be properly grown and leading to a defective deposition of Cu. Such defective Cu deposition has become a major cause for a decreased yield of semiconductor devices.

### SUMMARY OF THE INVENTION

Therefore, the present invention has been made in view of the above-mentioned problems occurring in the related/conventional art, and it is an object of the present invention to provide a method of manufacturing a semiconductor device, in which a wet-cleaning process is carried out to remove polymer and photoresist residues inside a contact hole, thereby enabling reduced defects in the deposition of a metallic material in the contact hole.

To accomplish the above object, the invention provides a method of manufacturing a semiconductor device, in which a metallic wiring is formed using a dual damascene process. In an embodiment of the invention, a first etching barrier film, an insulation film and a second etching barrier film are formed in sequence on a semiconductor substrate having a first metallic wiring, which is electrically connected with a lower portion of the semiconductor substrate. A first portion of the first etching barrier film and the insulation film is etched using a first photoresist pattern as a mask to form a contact hole, and then the first photoresist pattern is removed. A second portion of the first etching barrier film and the insulation film adjacent to the contact hole is etched using a second photoresist pattern to form a trench, and then the second photoresist pattern is removed. The contact hole is wet-cleaned. Then, the first etching barrier film exposed through the contact hole is etched and a reflection-preventing film and a second metallic wiring may be formed in the contact hole and the trench.

### BRIEF DESCRIPTION OF THE DRAWINGS

FIGS. 1A to 1H show procedures for forming a metallic wiring using a conventional dual damascene process in manufacturing semiconductor devices according to a conventional process.

FIGS. 2A to 2H illustrate procedures for forming a metallic wiring using a dual damascene process in manufacturing semiconductor devices according to an embodiment of the invention.

FIG. 3A shows polymer and residues remaining in the surface and the contact hole after a wet-etching in a conventional manufacturing process of semiconductor devices.

FIG. 3B shows a defective burial of Cu due to the polymer and residues remaining in the contact hole in a conventional manufacturing process of semiconductor devices.

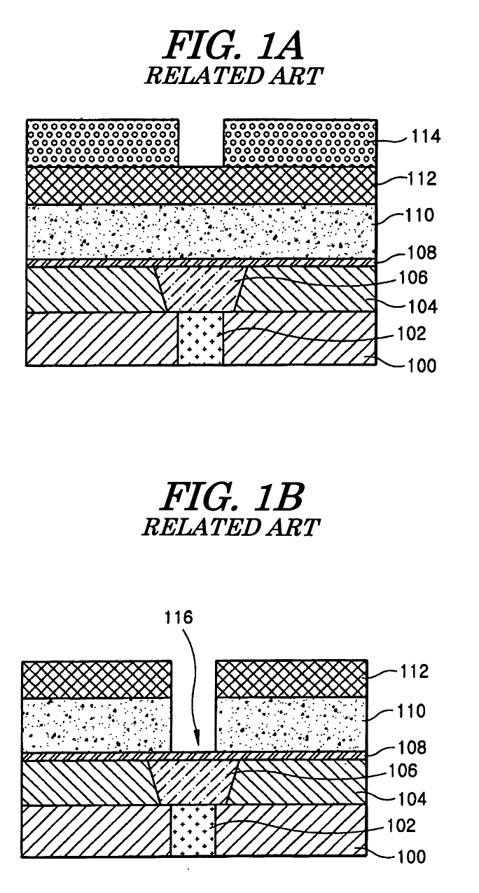

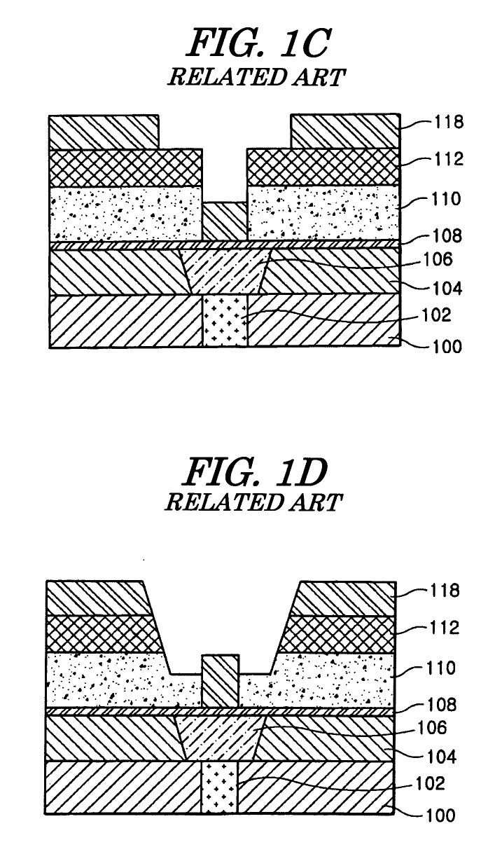

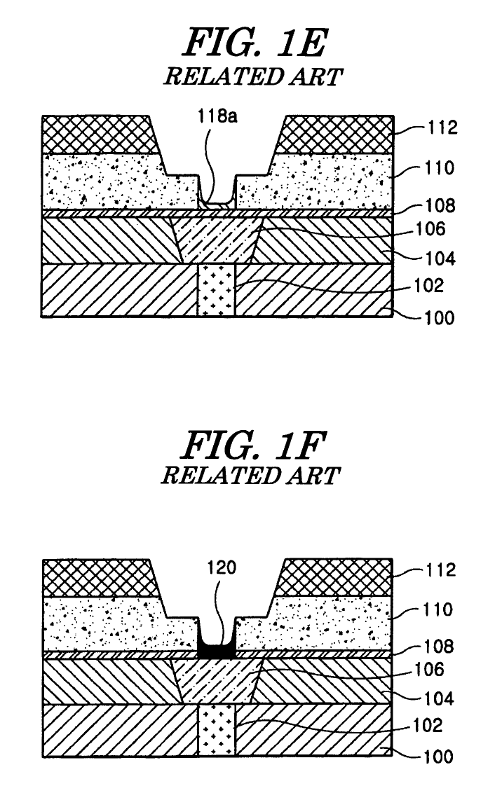

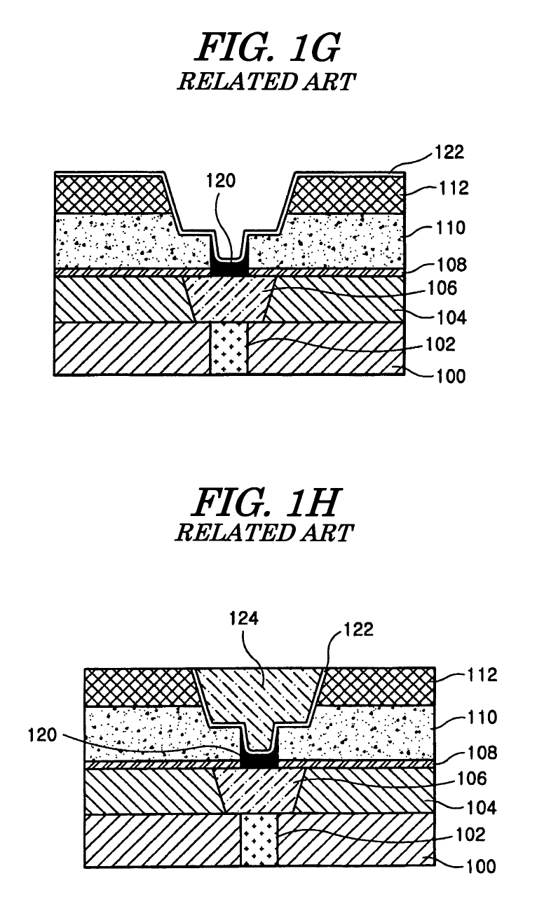

### DETAILED DESCRIPTION OF THE PREFERRED EMBODIMENT

The above and other objects and advantages of the invention will become more apparent to those skilled in the art from preferred embodiments of the invention, which will be hereafter described in greater detail with reference to the accompanying drawings.

One technical gist of the invention lies in that a contact hole is formed in a desired area of a semiconductor substrate and a trench is formed, and then the formed contact hole is wet-cleaned to remove a greater amount of photoresist residues and polymer that may remain inside the contact hole before forming a metallic wiring, as compared to conventional methods which may result in an increased incidence of defective deposition of metallic materials (e.g., open circuits) due to photoresist residues and polymer remaining inside the contact hole. Thus, the objects of the invention can be easily achieved through these features of the invention.

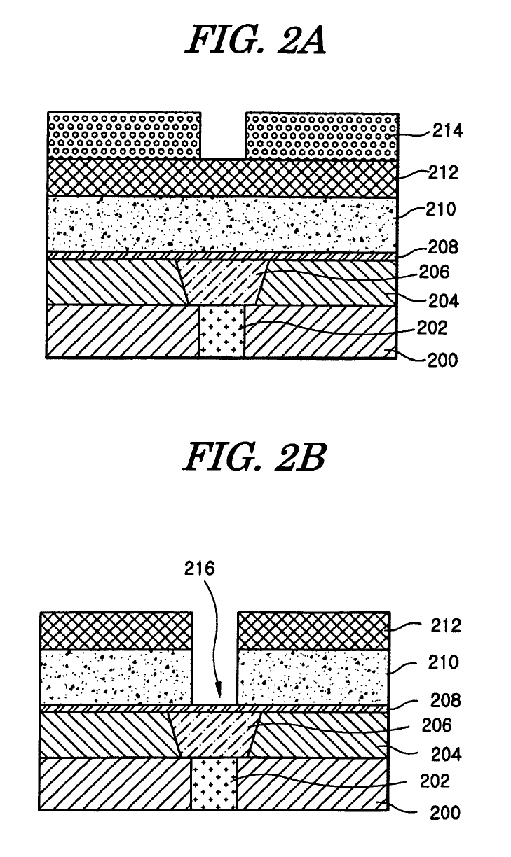

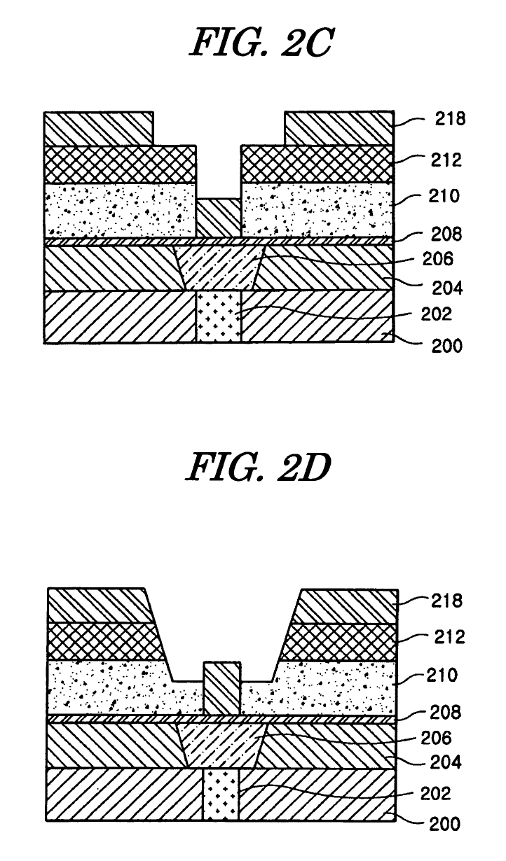

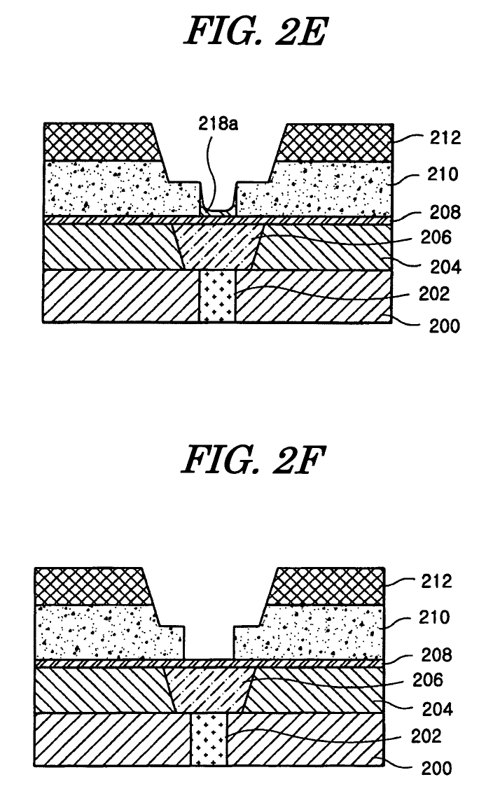

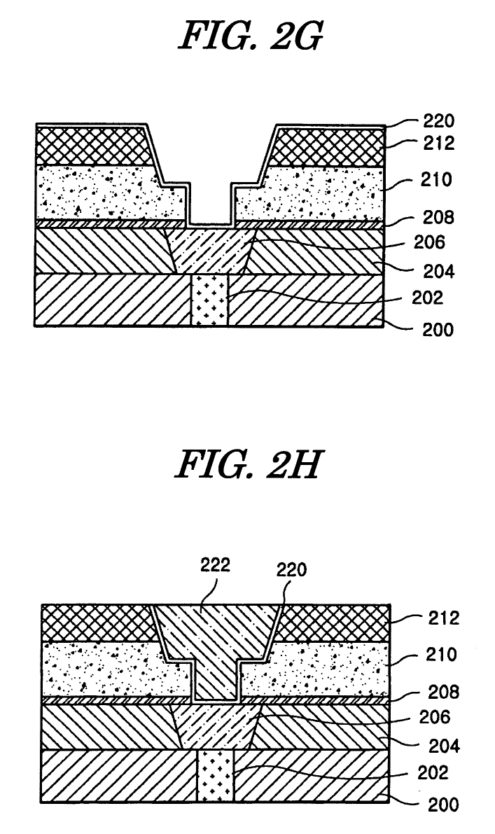

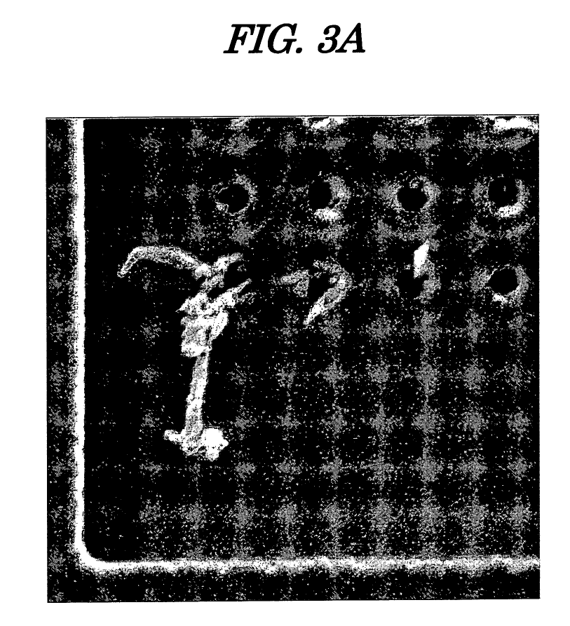

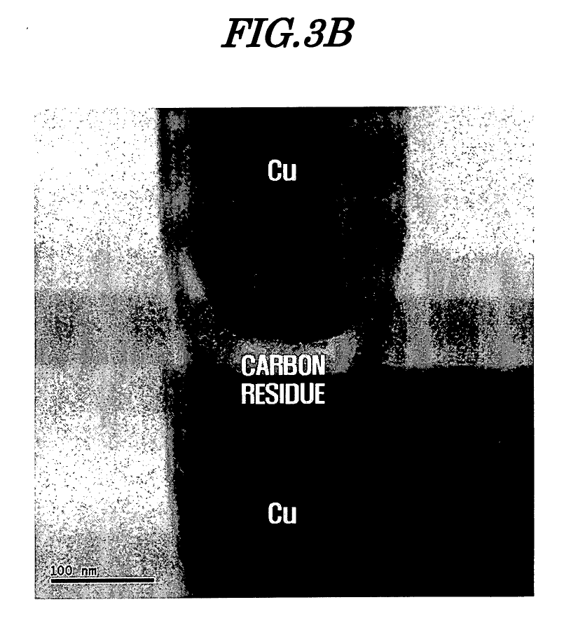

According to an embodiment of the invention, FIGS. 2A to 2H illustrate procedures for forming a metallic wiring using a dual damascene process in manufacturing semiconductor devices. The dual damascene process of this embodiment will be explained with reference to the figures.

Referring to FIG. 2A, a first (interlayer) insulation film 200 is patterned to form a contact hole, then the contact hole is conventionally filled with a first metal (e.g., tungsten) to form a contact plug 202. Then, a second (interlayer) insulation film 204 is formed thereon, patterned and conventionally filled with a second metal (e.g., copper) to form a first metallic wiring 206 on a semiconductor substrate. On top thereof, a first etching barrier film 208, and a third (interlayer) insulation film 210 and a second etching barrier film 212 are formed in sequence. While the first etching barrier film 208 and third insulation film 210 may comprise any materials providing a sufficiently high etching selectivity ratio under the conditions of etching the third insulation film 210 to enable the first etching barrier film 208 to effectively protect underlying materials from being or becoming etched (e.g., a ratio of the etching rate of the third insulation film 210 to the etching rate of the first etching barrier film 208 may be from 10:1 to 100:1 or more), in most cases, the first etching barrier film 208 comprises silicon nitride, and the third insulation film 210 comprises a silicon oxide (e.g., silicon dioxide, which may be undoped [e.g., a plasma silane- or TEOS-based oxide] or doped with one or more conventional dopants [e.g., fluorine, or boron and/or phosphorous]). The second etching barrier film 212 is generally a material providing a sufficiently high etching selectivity ratio under the conditions of etching or removing an overlying material (e.g., Ta, TaN and/or Cu) to enable the second etching barrier film 212 to effectively protect underlying materials from being or becoming etched or otherwise removed. In certain embodiments, the second etching barrier film 212 comprises a silicon oxide different from the third insulation film 210. For example, when the third insulation film 210 comprises a doped silicon oxide (e.g., FSG), the second etching barrier film 212 comprises an undoped silicon oxide (e.g., a plasma silane- or TEOS-based oxide). Thus, the second etching barrier film 212 may simply be a fourth insulator layer different from the third insulator layer 210 that is generally not significantly removed during the step of removing metal that may be deposited on the insulator film 212. Thereafter, a first photoresist pattern 214 is formed by conventional photolithography to form a contact hole pattern or mask.

In addition, as shown in FIG. 2B, a certain desired region (i.e., the contact hole regions) is etched along the first photoresist pattern 214 (i.e., using the first photoresist pattern 214 as a mask) so as to expose the first etching barrier film 208 and thereby form a contact hole 216. Then, the first photoresist pattern 214 is removed.

Thereafter, as shown in FIG. 2C, in order to form a trench, a second photoresist pattern 218 is formed on the semiconductor substrate having the contact hole 216. At times, a photoresist of certain thickness is in the contact hole 216. Generally, the second photoresist pattern 218 has openings for the trench that are wider than contact holes 216, and the trench openings in the second photoresist pattern 218 also generally completely expose contact holes 216.

Furthermore, as shown in FIG. 2D, the second etching barrier film 212 and a desired portion of the third insulation film 210 (e.g., to a predetermined or target depth less than the combined thicknesses of the barrier film 212 and the third insulation film 210) are dry-etched along the second photoresist pattern 218 to form a trench. Then, the second photoresist pattern 218 is removed, as shown in FIG. 2E. At this time, part of the photoresist 218a may remain along the inner side and lower surfaces of the contact hole 216.

Thereafter, as shown in FIG. 2F, a SiN wet-cleaning process is carried out to remove the polymer and photoresist residues resulting from any remaining photoresist 218a. Here, the SiN wet-cleaning process may be performed in sequence using DHCl (e.g., for about 25˜30 seconds at about 250˜350 RPM), DHF (e.g., for about 2˜12 seconds at about 400˜500 RPM in a first stage, for about 2˜12 seconds at about 0 RPM in a second stage, and for about 1˜6 seconds at about 400˜500 RPM in a third stage) and DNH₄OH (e.g., for about 3˜10 seconds at about 1400˜1500 RPM). Here, “cleaning” or “wet-cleaning” refers to immersion in a bath containing the DHCl, DHF or DNH₄OH, or spraying the substrate with the DHCl, DHF or DNH₄OH. Also, “performed at [x] RPM” refers to rotating or spinning the substrate at the specified number (“x”) of revolutions per minute, generally in the cleaning apparatus. In addition, the SiN wet-cleaning process may expand the contact hole 216 to have a larger interface. Here, ‘D’ in DHCl, DHF and DNH₄OH denotes ‘diluted’(e.g., one part by weight or volume of concentrated aqueous HCl, HF and NH₄OH are diluted with one or more parts by weight, volume or moles of deionized and/or distilled water). Any combination or subcombination of the three DHF stages is contemplated by the invention, but preferably, the first stage is performed at a speed of at least 400 RPM, and the second stage is performed at a speed of 0 RPM. Preferably, the third stage is performed at a speed of at least 400 RPM.

Then, the first etching barrier film 208 at the bottom of the (expanded) contact hole 216 is dry-etched. Thereafter, using a CVD method, a metallic barrier film 220 of TaN/Ta or the like is deposited over the whole top surface of the above-configured semiconductor substrate, as shown in FIG. 2G.

Subsequently, as shown in FIG. 2H, a thin “seed” layer of metallic material such as Cu, Ru or the like is vapor-deposited on the metallic barrier film 220 of the semiconductor substrate. A bulk layer of metallic material such as Cu or the like may then be electroplated or electrolessly deposited on the thin “seed” layer. Then, using chemical mechanical polishing (CMP), an etchback process or the like, a flattening or planarizing process is performed so as to expose the second etching barrier film 212, thus a metallic wiring 222 is formed.

Therefore, polymer and photoresist residues, which may occur inside the contact hole through reaction of remaining photoresist and SiN during the device manufacturing process, are efficiently removed using a SiN wet-cleaning process to thereby enable to prevent defective deposition of a metallic material.

As described above, in a method of manufacturing a semiconductor device using a dual damascene process, the invention forms a contact hole in a desired area of a semiconductor substrate and a trench having a larger area than the contact hole. Then, the contact hole is wet-cleaned to remove photoresist residues and polymers. Thereafter, a metallic wiring is formed on or in a desired region. Thus, photoresist residues and polymer inside the contact hole can be removed to avoid defective deposition of a metallic material, dissimilar to conventional methods which can cause defective deposition of metallic materials due to an increased incidence of photoresist residues and polymer remaining inside the contact holes.

Thus, in the manufacturing process of a semiconductor device, a contact plug and a metallic wire can be formed while avoiding defects in deposition of metallic materials (such as open circuits), thereby enabling improvements in the yield and productivity of semiconductor devices.

Although the present invention has been described with reference to certain embodiments, the description is illustrative of the invention and not to be construed as limiting the invention. Various modifications and variations may occur to those skilled in the art, without departing from the scope and spirit of the invention as defined by the appended claims.

What is claimed is:

1. A method of manufacturing a semiconductor device, comprising:
forming in sequence a first etching barrier film, an insulation film and a second etching barrier film on a semiconductor substrate having a first metallic wiring, the first metallic wiring being electrically connected with a lower portion of the semiconductor substrate;
etching a first portion of the first etching barrier film and the insulation film using a first photoresist pattern as a mask to form a contact hole, and removing the first photoresist pattern;
etching a second portion of the first etching barrier film and the insulation film using a second photoresist pattern to form a trench, the second photoresist pattern exposing a portion of the contact hole, and removing the second photoresist pattern;
wet-cleaning the contact hole; and
etching the first etching barrier film exposed through the contact hole, and then forming a second metallic wiring.

2. The method of claim 1, wherein wet-cleaning comprises cleaning the semiconductor device with dilute hydrochloric acid (DHCl).

3. The method of claim 2, wherein wet-cleaning further comprises cleaning the semiconductor device with dilute ammonium hydroxide (DNH₄OH).

4. The method of claim 3, wherein wet-cleaning further comprises cleaning the semiconductor device with dilute hydrofluoric acid (DHF).

5. The method of claim 3, wherein wet-cleaning comprises cleaning the semiconductor device with DHCl, DHF and DNH₄OH in sequence.

6. The method of claim 2, wherein cleaning with DHCl is performed for 25 to 30 seconds.

7. The method of claim 2, wherein cleaning with DHCl is performed at 250 to 350 RPM.

8. The method of claim 6, wherein cleaning with DHCl is performed at 250 to 350 RPM.

9. The method of claim 4, wherein cleaning with DHF is performed at 400 to 500 RPM.

10. The method of claim 4, wherein cleaning with DHF is performed for 5 to 30 seconds.

11. The method of claim 9, wherein cleaning with DHF is performed in a first stage for 2 to 12 seconds at 400 to 500 RPM, then in a second stage at 0 RPM.

12. The method of claim 11, wherein the second stage is performed for 2 to 12 seconds.

13. The method of claim 12, wherein cleaning with DHF is further performed in a third stage at 400 to 500 RPM after the second stage.

14. The method of claim 13, wherein the third stage is performed for 1 to 6 seconds.

15. The method of claim 3, wherein cleaning with DNH₄OH is performed for 3 to 10 seconds.

16. The method of claim 15, wherein cleaning with DNH₄OH is performed at 1400 to 1500 RPM.

17. A method of manufacturing a semiconductor device, comprising:
etching a contact hole in first and second insulation films on a semiconductor substrate having a first etching barrier film and a first metallic wiring below the first and second insulation films, the first metallic wiring being electrically connected to a lower portion of the semiconductor substrate;
etching a trench in a portion of the first and second insulation films overlapping the contact hole;
wet-cleaning the semiconductor device with dilute hydrochloric acid (DHCl), dilute hydrofluoric acid (DHF), and dilute ammonium hydroxide (DNH₄OH), wherein wet-cleaning with DHF comprises cleaning the semiconductor device with DHF in a first stage for at least 2 seconds at a speed of at least 400 RPM, then in a second stage for at least 2 seconds at 0 RPM; and
etching the first etching barrier film exposed through the contact hole.

18. The method of claim 17, wherein cleaning with DHF is further performed in a third stage at a speed of at least 400 RPM after the second stage.

19. The method of claim 18, wherein the third stage is performed for at least 1 second.

20. The method of claim 19, wherein the first stage has a maximum time of 12 seconds and a maximum speed of 500 RPM, and the third stage has a maximum time of 6 seconds and a maximum speed of 500 RPM.
